(19) United States
(12) Patent Application Publication
(10) Pub. No.: US 2025/0119144 A1
(43) Pub. Date: Apr. 10, 2025

(54) PREPARATION METHOD OF BISMUTH OXIDE FILM AND RECONFIGURABLE PHOTOELECTRIC LOGIC GATE

(71) Applicant: Institute of Analysis, Guangdong Academy of Sciences (China National Analytical Center, Guangzhou), Guangzhou (CN)

(72) Inventors: Fuxian WANG, Guangzhou (CN); Boheng DONG, Guangzhou (CN); Qiong LIU, Guangzhou (CN)

(73) Assignee: Institute of Analysis, Guangdong Academy of Sciences (China National Analytical Center, Guangzhou), Guangzhou (CN)

(21) Appl. No.: 18/729,903

(22) PCT Filed: Sep. 26, 2022
(86) PCT No.: PCT/CN2022/121276

§ 371 Date: Jul. 18, 2024

(30) Foreign Application Priority Data
Sep. 15, 2022 (CN) 202211124468.2

(51) Int. Cl. H03K 19/14; C23C 14/16; C23C 14/34; C23C 14/35; C23C 14/58

(52) U.S. Cl. CPC H03K 19/14; C23C 14/165; C23C 14/3414; C23C 14/35; C23C 14/5853

(57) ABSTRACT

A preparation method of a bismuth oxide film and a reconfigurable photoelectric logic gate are provided. It is discovered for the first time that an open-circuit photovoltage of bismuth oxide varies non-monotonically with a light intensity. A reconfigurable photoelectric logic gate is designed and manufactured by using the unique property of bismuth oxide. By adjusting an input light intensity, various logic gates such as an XOR gate, an AND gate, a NAND gate, an OR gate, a NOR gate, a NOT gate, and an AND-NOT gate can be programmably reconfigured by using a single device, without changing a threshold condition. Compared with a conventional electronic logic gate, a photoelectric logic gate having the characteristic of flexible and diversified programmable reconfigurations can implement more complex operation and calculation with fewer components, thereby being expected to play an important role in the upcoming Internet of Things era in which information increases explosively.

### TECHNICAL FIELD

The present invention relates to the technical field of integrated circuits and processors, and specifically, to a preparation method of a bismuth oxide film, and reconfigurable photoelectric logic gate based on the non monotonic variation of bismuth oxide open circuit photovoltage with light intensity.

### BACKGROUND

Conventional complementary metal oxide semiconductor (CMOS)-based logical calculation devices have followed Moore's Law in the past few decades, and continuously shrink in size to increase a quantity of transistors, thereby meeting increasing demands of data processing. It is expected that in the fourth industrial revolution era and the Internet of Things era, the amount of data will increase explosively and even exceed an allowed range in the Moore's Law. The conventional CMOS-based logical calculation devices will face severe limitations in computing massive data sets. Compared with device size shrinking and three-dimensional integration, developing a novel reconfigurable logic gate is a very promising direction.

Photoelectric logic gates can be used for processing data accurately and fast, thereby having received extensive attention. Particularly, different logic gates can be switched flexibly on a single device by programming a reconfigurable photoelectric logic gate, so that more complex data operation and calculation can be implemented using fewer components. At present, reconfigurable photoelectric logic gates capable of switching basic logic gates such as an AND gate, a OR gate, and an NOT gate have been reported. However, reconfigurable photoelectric logic gates capable of implementing XOR operation are rarely reported.

An XOR logic gate is not only an important element of data processing functions such as bit pattern recognition, data encryption, parity check, and signal regeneration, but also a fundamental tool for synchronization, erasure, and replacement in a packet switching network. Difficulty in implementing operation of a photoelectric XOR gate is that outputting 0 for inputs (1,1) cannot be implemented when both outputting 0 for inputs (0,0) and outputting 1 for inputs (1,0) are implemented, which is essentially a non-monotonic variation. An output of an existing photoelectric logic gate device varies monotonically with an input light intensity. As a result, XOR gate operation cannot be implemented. In some reports, photocurrents in different directions are used to implement XOR gate operation, but additionally determining absolute values of the photocurrents is required for determining an output result, which increases complexity of logical judgment. In addition, under a certain light intensity, a photocurrent increases with a device size. Therefore, a logic gate that is based on a photocurrent signal has very high requirement on device processing accuracy.

### SUMMARY

To overcome the above deficiencies of the existing technology, the present invention provides a preparation method of a bismuth oxide film, and reconfigurable photoelectric logic gate based on the non monotonic variation of bismuth oxide open circuit photovoltage with light intensity, and designs and manufactures a reconfigurable photoelectric logic gate by using the unique property of bismuth oxide. By adjusting an input light intensity, various logic gates such as an XOR gate, an AND gate, a NAND gate, an OR gate, a NOR gate, a NOT gate, and an AND-NOT gate can be programmably reconfigured by using a single device, without changing a threshold condition.

To achieve the above objective, the present invention adopts the following technical solutions.

According to a first aspect, the present invention provides a preparation method of a bismuth oxide film. The method comprises the following steps:
(1) depositing bismuth on a conductive substrate to obtain a bismuth film, wherein bismuth metal is used as a target material, a sputtering power is controlled to be 20 W to 80 W, a deposition time is controlled to be 15 s to 900 s, a substrate rotation speed is controlled to be 0 r/min to 25 r/min, a substrate temperature is controlled to be 300 K to 620 K, a sputtering pressure is controlled to be 0.7 pa to 3.5 pa, an argon gas is introduced as a carrier gas in a sputtering process, and a flow rate of the argon gas is controlled to be 5 mL/min to 60 mL/min; and
(2) calcining, in air, the bismuth film prepared in step (1) to obtain the bismuth oxide film.

Preferably, in step (1), a magnetron sputtering method is used to deposit the bismuth on the conductive substrate to obtain the bismuth film.

Preferably, in step (2), a temperature of the calcining is controlled to be 450 K to 720 K; and the calcining is carried out in any one of a heating table, a high-temperature oven, and a tubular heating furnace.

According to a second aspect, the present invention provides reconfigurable photoelectric logic gate based on the non monotonic variation of bismuth oxide open circuit photovoltage with light intensity, comprising a working electrode, wherein the working electrode is a bismuth oxide film deposited on a conductive substrate, and the bismuth oxide film is prepared according to the above preparation method.

Preferably, the reconfigurable photoelectric logic gate based on the non monotonic variation of bismuth oxide open circuit photovoltage with light intensity further comprising an input light source, a modulator, a counter electrode, an electrolyte and an electrolytic cell, wherein the input light source comprises a first input light source and a second input light source;
the input light source and the modulator are used to emit light that is used as input light to illuminate a same position of the working electrode;
the working electrode is fixed inside the electrolytic cell; and the electrolytic cell serves as a container for the electrolyte; and
the counter electrode is fixed inside the electrolytic cell and does not block the light emitted by the input light source and the modulator.

Preferably, the conductive substrate is one of stainless steel, a copper sheet, an aluminum sheet, indium tin oxide glass, a conductive silicon wafer, and fluorine-doped tin oxide glass.

Preferably, the counter electrode is one of a platinum sheet, a copper sheet, a silver/silver chloride electrode, and a calomel electrode.

Preferably, the input light source has a wavelength of 365 nm to 450 nm and a light intensity of 0.01 mW/cm² to 25 mW/cm².

According to a third aspect, the present invention provides an assembly method of a reconfigurable photoelectric logic gate. The method is based on the above reconfigurable photoelectric logic gate, and comprises the following steps:
using quartz glass as a light input window;
fixing the working electrode inside the electrolytic cell and opposite to the quartz glass window, to ensure that the input light is capable of illuminating the working electrode;
fixing the counter electrode inside the electrolytic cell, without blocking a light path of the input light; and
fixing three light sources as the first input light source, the second input light source, and the modulator respectively; and adjusting the light path to cause the first input light source, the second input light source, and the modulator illuminate a same position of the working electrode.

According to a fourth aspect, the present invention provides a method for implementing logical calculation of a reconfigurable photoelectric logic gate, wherein the reconfigurable photoelectric logic gate is assembled according to the above assembly method, and the method comprises the following steps:
injecting the electrolyte into the electrolytic cell, controlling switches and light intensities of the first input light source, the second input light source, and the modulator, marking on states of the first input light source and the second input light source as 1, and marking off states of the first input light source and the second input light source as 0;
using a voltmeter to detect variations of open-circuit voltages at both ends of each of the working electrode and the counter electrode, and determining the open-circuit voltage as 1 when the open-circuit voltage is greater than a threshold, or determining the open-circuit voltage as 0 when the open-circuit voltage is less than the threshold; and
adjusting the light intensities of the first input light source, the second input light source, and the modulator, to freely reconfigure an XOR gate, a multi-input XOR gate, an AND gate, a NAND gate, an OR gate, a NOR gate, a NOT gate, and an AND-NOT gate on a single device, without changing the threshold.

Compared with the prior art, the present invention has the following beneficial effects:

By using a bismuth oxide film that is prepared according to the preparation method of a bismuth oxide film provided in the present invention, it is discovered for the first time that an open-circuit photovoltage varies non-monotonically with a light intensity; and a reconfigurable photoelectric logic gate is designed and manufactured by using the unique property of bismuth oxide. By adjusting an input light intensity, the reconfigurable photoelectric logic gate can implement programmable reconfiguration of various logic gates such as an XOR gate, an AND gate, a NAND gate, an OR gate, a NOR gate, a NOT gate, and an AND-NOT gate by using a single device, without changing a threshold condition.

In addition, using the magnetron sputtering coating technology to prepare the bismuth oxide film facilitates large-scale and low-cost production of devices.

### BRIEF DESCRIPTION OF THE DRAWINGS

FIG. 1 is a schematic diagram of reconfigurable photoelectric logic gate based on the non monotonic variation of bismuth oxide open circuit photovoltage with light intensity according to an embodiment of the present invention.

FIG. 2 is a curve chart of an open-circuit voltage, that varies with a light intensity, of reconfigurable photoelectric logic gate based on the non monotonic variation of bismuth oxide open circuit photovoltage with light intensity according to an embodiment of the present invention.

FIG. 3 shows signal outputs of an XOR gate.

FIG. 4 shows signal outputs of a 3-input XOR gate.

FIG. 5 shows signal outputs of an AND gate.

FIG. 6 shows signal outputs of a NAND gate.

FIG. 7 shows signal outputs of an OR gate.

FIG. 8 shows signal outputs of a NOR gate.

FIG. 9 shows signal outputs of an AND-NOT gate.

### DETAILED DESCRIPTION OF THE EMBODIMENTS

The technical solution of the present invention will be further described below with reference to the accompanying drawings and examples.

### Embodiment 1

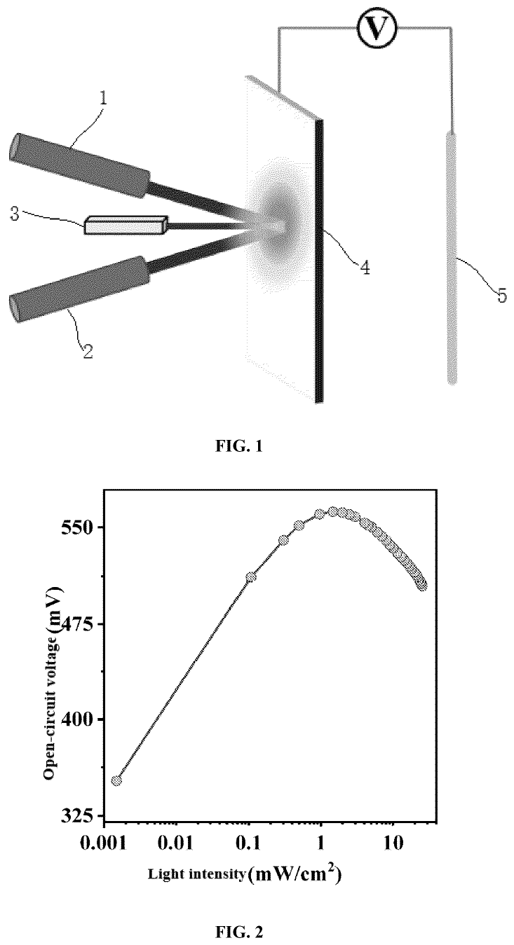

Referring to FIG. 1, reconfigurable photoelectric logic gate based on the non monotonic variation of bismuth oxide open circuit photovoltage with light intensity provided in this example mainly comprises an input light source, a modulator 3, a working electrode 4, a counter electrode 5, an electrolyte, and an electrolytic cell, wherein the input light source comprises a first input light source 1 and a second input light source 2;
the input light source and the modulator 3 are used to emit light that is used as input light to illuminate a same position of the working electrode; the working electrode is fixed inside the electrolytic cell; the electrolytic cell serves as a container for the electrolyte; and the counter electrode is fixed inside the electrolytic cell and does not block the light emitted by the input light source and the modulator.

Specifically, wavelengths of the input light source and the modulator are 405 nm; the working electrode is bismuth oxide deposited on a stainless steel substrate; and the counter electrode is a silver/silver chloride electrode. Certainly, the wavelengths and light intensities of the input light source and the modulator only need to range from 365 nm to 450 nm, and 0.01 mW/cm² to 25 mW/cm² respectively.

Preparation of the working electrode comprises the following steps:
(1) using a magnetron sputtering method to deposit bismuth on the stainless steel substrate to obtain a bismuth film, wherein bismuth metal is used as a target material, a sputtering power is controlled to be 40 W, a deposition time is controlled to be 120 s, a substrate rotation speed is controlled to be 20 r/min, a substrate temperature is controlled to be 370 K (Kelvin temperature), a sputtering pressure is controlled to be 1.0 pa, an argon gas is introduced as a carrier gas in a sputtering process, and a flow rate of the argon gas is controlled to be 30 mL/min; and
(2) calcining, in air, the bismuth film prepared in step (1) to obtain the bismuth oxide film, wherein a temperature of the calcining is controlled to be 620 K, and the calcining is carried out in a heating table.

### Embodiment 2

A difference from Embodiment 1 lies in preparation of the working electrode.

The preparation of the working electrode comprises the following steps:
(1) using a magnetron sputtering method to deposit bismuth on the stainless steel substrate to obtain a bismuth film, wherein bismuth metal is used as a target material, a sputtering power is controlled to be 80 W, a deposition time is controlled to be 120 s, a substrate rotation speed is controlled to be 15 r/min, a substrate temperature is controlled to be 420 K, a sputtering pressure is controlled to be 1.5 pa, an argon gas is introduced as a carrier gas in a sputtering process, and a flow rate of the argon gas is controlled to be 25 mL/min; and
(2) calcining, in air, the bismuth film prepared in step (1) to obtain the bismuth oxide film, wherein a temperature of the calcining is controlled to be 570 K, and the calcining is carried out in a heating table.

### Embodiment 3

A difference from Embodiment 1 lies in preparation of the working electrode.

The preparation of the working electrode comprises the following steps:
(1) using a magnetron sputtering method to deposit bismuth on the stainless steel substrate to obtain a bismuth film, wherein bismuth metal is used as a target material, a sputtering power is controlled to be 20 W, a deposition time is controlled to be 360 s, a substrate rotation speed is controlled to be 10 r/min, a substrate temperature is controlled to be 320 K, a sputtering pressure is controlled to be 0.8 pa, an argon gas is introduced as a carrier gas in a sputtering process, and a flow rate of the argon gas is controlled to be 20 mL/min; and
(2) calcining, in air, the bismuth film prepared in step (1) to obtain the bismuth oxide film, wherein a temperature of the calcining is controlled to be 520 K, and the calcining is carried out in a heating table.

### Embodiment 4

This example provides an assembly method of a reconfigurable photoelectric logic gate. The reconfigurable photoelectric logic gate is the reconfigurable photoelectric logic gate according to any one of examples 1 to 3. The method specifically comprises the following steps:
(1) using quartz glass with a thickness of 1 mm as a light input window;
(2) fixing the working electrode inside the electrolytic cell and opposite to the quartz glass window, to ensure that the input light is capable of illuminating the working electrode;
(3) fixing the counter electrode inside the electrolytic cell, without blocking a light path of the input light; and
(4) fixing three light sources as the first input light source, the second input light source, and the modulator respectively; and adjusting the light path to cause the first input light source, the second input light source, and the modulator illuminate a same position of the working electrode.

### Experimental Embodiment 1

### 1. A Curve of a Photovoltage Varying With a Light Intensity was Obtained

A two-electrode system was used; after the above working electrode obtained in Embodiment 4 was assembled, the electrolyte was added into the electrolytic cell; and a voltmeter was connected to the working electrode and the counter electrode. The working electrode was illuminated with light of different intensities; and a curve of an open-circuit photovoltage varying with a light intensity was recorded, as shown in FIG. 2. When the light intensity was small, the open-circuit photovoltage increased with the light intensity. Then, as the light intensity increased, the open-circuit photovoltage reached a maximum value. Then, the light intensity increased continuously, and it was found that the open-circuit photovoltage decreased with the increase of the light intensity. That is to say, by using a bismuth oxide film that is prepared according to the preparation method of a bismuth oxide film provided in the present invention, the open-circuit photovoltage showed a non-monotonous variation trend with the increase of the light intensity. However, a current classical theory suggests that an open-circuit photovoltage is directly proportional to a logarithm of a light intensity; and there are no reports in related literature about non-monotonous variation of a photovoltage with increase of a light intensity. Therefore, it is discovered for the first time that an open-circuit photovoltage of bismuth oxide varies non-monotonically with a light intensity. A reconfigurable photoelectric logic gate is designed and manufactured by using the unique property of bismuth oxide.

### Experimental Embodiment 2

### 1. Implementation of an XOR Gate

A logic gate was reconfigured by adjusting light intensities of input and the modulator, to implement the XOR gate.

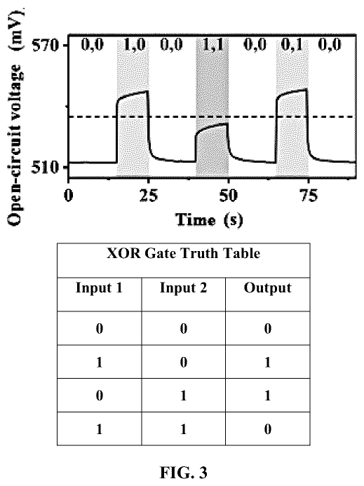

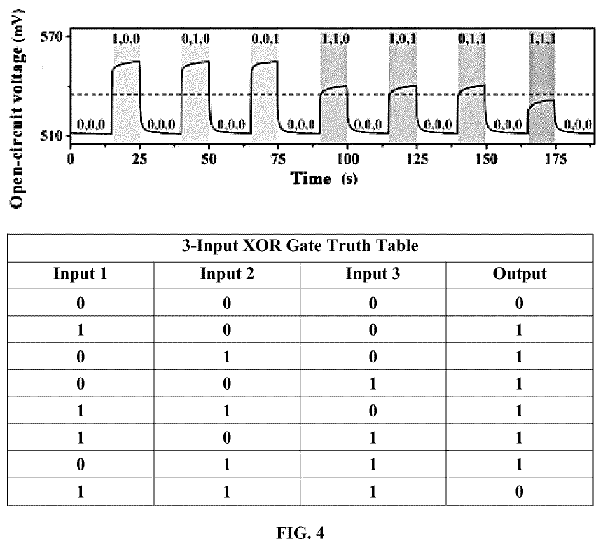

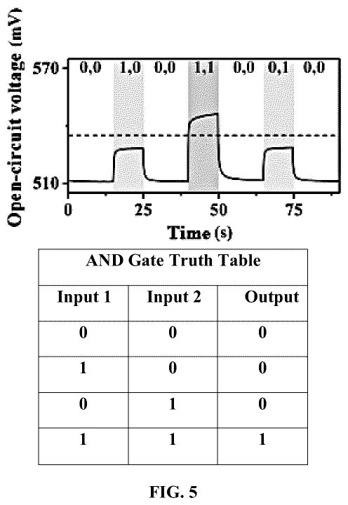

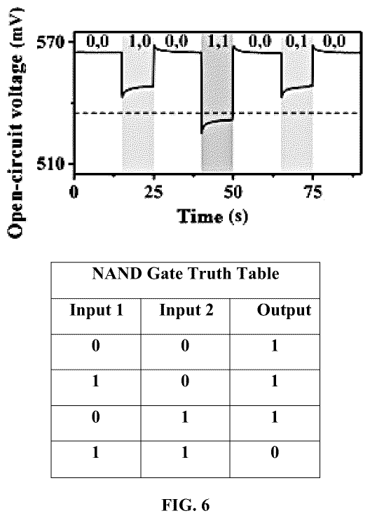

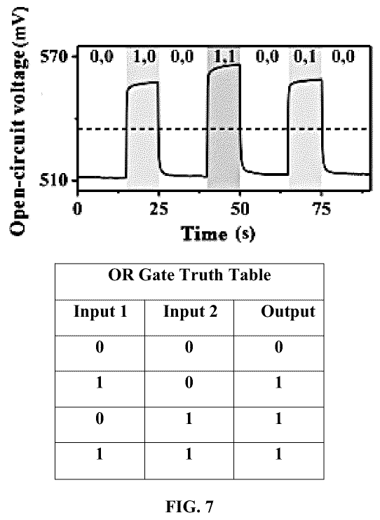

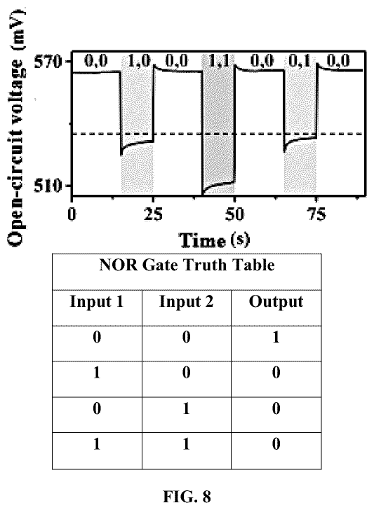

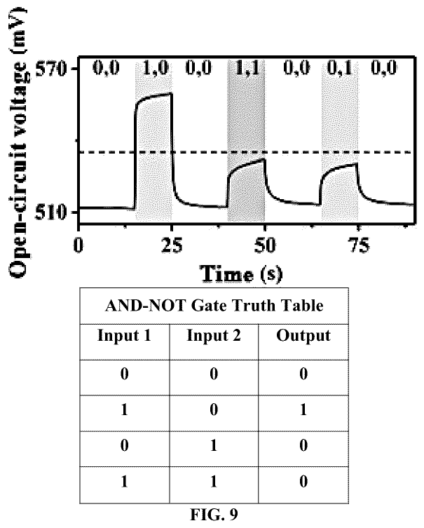

A property of an open-circuit photovoltage of bismuth oxide of non-monotonically varying with a light intensity was used to implement XOR gate operation. Specifically, the light intensity of the modulator was set to 0.11 mW/cm²; the light intensity of the first input light source was set to 5.21 mW/cm²; and the light intensity of the second input light source was set to 5.21 mW/cm². 1 was recorded when the input light source was turned on; and 0 was recorded when the input light source was turned off. An output threshold was recorded as 535 mV, that is, 1 was recorded when an output open-circuit photovoltage was greater than 535 mV, and 0 was recorded when the output open-circuit photovoltage was less than 535 mV. Signal outputs and a truth table of the XOR gate are shown in FIG. 3, and are consistent with each other. This indicates that the XOR gate was configured successfully.

### 2. Implementation of a Multi-Input XOR Gate

A logic gate was reconfigured by adjusting light intensities of input and the modulator, to implement the multi-input XOR gate.

A current multi-input XOR gate is not real “same 0, different 1”. Cui Jianguo and others designed a multi-input XOR gate by using a conventional electronic logic circuit, thereby implementing real “same 0, different 1”. However, the multi-input XOR gate has a very complex structure and is not reconfigurable, which limits its practical application. In this patent, by adjusting the light intensities of input and the modulator, a real “same 0, different 1” multi-input XOR gate can be implemented by using a single device.

The following uses a 3-input XOR gate as an example. Specifically, the light intensity of the modulator was set to 0.11 mW/cm²; the light intensity of the first input light source was set to 3.83 mW/cm²; the light intensity of the second input light source was set to 3.83 mW/cm²; and a light intensity of input 3 was set to 3.83 mW/cm². 1 was recorded when the input light source was turned on; and 0 was recorded when the input light source was turned off. An output threshold was recorded as 535 mV, that is, 1 was recorded when an output open-circuit photovoltage was greater than 535 mV, and 0 was recorded when the output open-circuit photovoltage was less than 535 mV. Signal outputs and a truth table of the 3-input XOR gate are shown in FIG. 3, and are consistent with each other. This indicates that the 3-input XOR gate was configured successfully. A 4-input XOR gate can be configured by changing a light intensity of a first input light source-4 to 2.61 mW/cm². A 5-input XOR gate can be configured by changing a light intensity of a first input light source-5 to 2.09 mW/cm².

### 3. Implementation of an AND Gate

A logic gate was reconfigured by adjusting light intensities of input and the modulator, to implement the AND gate.

Specifically, the light intensity of the modulator was set to 0.11 mW/cm²; the light intensity of the first input light source was set to 0.13 mW/cm²; and the light intensity of the second input light source was set to 0.13 mW/cm². 1 was recorded when the input light source was turned on; and 0 was recorded when the input light source was turned off. An output threshold was recorded as 535 mV, that is, 1 was recorded when an output open-circuit photovoltage was greater than 535 mV, and 0 was recorded when the output open-circuit photovoltage was less than 535 mV. Signal outputs and a truth table of the AND gate are shown in FIG. 3, and are consistent with each other. This indicates that the AND gate was configured successfully.

### 4. Implementation of a NAND Gate

A logic gate was reconfigured by adjusting light intensities of input and the modulator, to implement the NAND gate.

Specifically, the light intensity of the modulator was set to 0.99 mW/cm²; the light intensity of the first input light source was set to 5.21 mW/cm²; and the light intensity of the second input light source was set to 5.21 mW/cm². 1 was recorded when the input light source was turned on; and 0 was recorded when the input light source was turned off. An output threshold was recorded as 535 mV, that is, 1 was recorded when an output open-circuit photovoltage was greater than 535 mV, and 0 was recorded when the output open-circuit photovoltage was less than 535 mV. Signal outputs and a truth table of the NAND gate are shown in FIG. 3, and are consistent with each other. This indicates that the NAND gate was configured successfully.

### 5. Implementation of an OR Gate

A logic gate was reconfigured by adjusting light intensities of input and the modulator, to implement the OR gate.

Specifically, the light intensity of the modulator was set to 0.11 mW/cm²; the light intensity of the first input light source was set to 0.51 mW/cm²; and the light intensity of the second input light source was set to 0.51 mW/cm². 1 was recorded when the input light source was turned on; and 0 was recorded when the input light source was turned off. An output threshold was recorded as 535 mV, that is, 1 was recorded when an output open-circuit photovoltage was greater than 535 mV, and 0 was recorded when the output open-circuit photovoltage was less than 535 mV. Signal outputs and a truth table of the OR gate are shown in FIG. 3, and are consistent with each other. This indicates that the OR gate was configured successfully.

### 6. Implementation of an NOR Gate and a NOT Gate

A logic gate was reconfigured by adjusting light intensities of input and the modulator, to implement the NOR gate and the NOT gate.

Specifically, the light intensity of the modulator was set to 0.99 mW/cm²; the light intensity of the first input light source was set to 10.45 mW/cm²; and the light intensity of the second input light source was set to 10.45 mW/cm². 1 was recorded when the input light source was turned on; and 0 was recorded when the input light source was turned off. An output threshold was recorded as 535 mV, that is, 1 was recorded when an output open-circuit photovoltage was greater than 535 mV, and 0 was recorded when the output open-circuit photovoltage was less than 535 mV. Signal outputs and a truth table of the NOR gate are shown in FIG. 3, and are consistent with each other. This indicates that the NOR gate was configured successfully. The NOT gate can be obtained only by changing two inputs of the NOR gate into a single input.

### 7. Implementation of an NOR Gate and a NOT Gate

A logic gate was reconfigured by adjusting light intensities of input and the modulator, to implement the AND-NOT gate.

Specifically, the light intensity of the modulator was set to 0.11 mW/cm²; the light intensity of the first input light source was set to 0.51 mW/cm²; and the light intensity of the second input light source was set to 11.31 mW/cm². 1 was recorded when the input light source was turned on; and 0 was recorded when the input light source was turned off. An output threshold was recorded as 535 mV, that is, 1 was recorded when an output open-circuit photovoltage was greater than 535 mV, and 0 was recorded when the output open-circuit photovoltage was less than 535 mV. Signal outputs and a truth table of the AND-NOT gate are shown in FIG. 3, and are consistent with each other. This indicates that the AND-NOT gate was configured successfully.

In summary, the present invention develops reconfigurable photoelectric logic gate based on the non monotonic variation of bismuth oxide open circuit photovoltage with light intensity. By adjusting an input light intensity, various logic gates such as various logic gates such as an XOR gate, an AND gate, a NAND gate, an OR gate, a NOR gate, a NOT gate, and an AND-NOT gate can be programmably reconfigured by using a single device, without changing a threshold condition. Because an open-circuit voltage is independent of a device size and is an intrinsic property of a photoelectric material, a photoelectric logic gate signal based on an open-circuit voltage signal in the present invention does not vary with a device size. This greatly reduces a requirement on processing accuracy of a device, so that it is expected to significantly reduce processing costs of the device. Compared with a conventional electronic logic gate, the photoelectric logic gate provided in the present invention and having the characteristic of flexible and diversified programmable reconfigurations is expected to implement more complex operation and calculation with fewer components, thereby showing a great application prospect in the upcoming Internet of Things era in which information increases explosively.

The above examples are only for explaining the technical concept and features of the present invention, and the objective thereof is to enable those of ordinary skill in the art to understand the content of the present invention and implement therefrom, but not to limit the protection scope of the present invention. Any equivalent changes or modifications made according to the essence of the present invention shall fall within the protection scope of the present invention.

What is claimed is:

1. A preparation method of a bismuth oxide film, comprising the following steps:
(1) depositing bismuth on a conductive substrate to obtain a bismuth film, wherein bismuth metal is used as a target material, a sputtering power is controlled to be 20 W to 80 W, a deposition time is controlled to be 15 s to 900 s, a substrate rotation speed is controlled to be 0 r/min to 25 r/min, a substrate temperature is controlled to be 300 K to 620 K, a sputtering pressure is controlled to be 0.7 pa to 3.5 pa, an argon gas is introduced as a carrier gas in a sputtering process, and a flow rate of the argon gas is controlled to be 5 mL/min to 60 mL/min; and
(2) calcining, in air, the bismuth film prepared in step (1) to obtain the bismuth oxide film.

2. The preparation method of the bismuth oxide film according to claim 1, wherein in step (1), a magnetron sputtering method is used to deposit the bismuth on the conductive substrate to obtain the bismuth film.

3. The preparation method of the bismuth oxide film according to claim 1, wherein in step (2), a temperature of the calcining is controlled to be 450 K to 720 K; and the calcining is carried out in any one of a heating table, a high-temperature oven, and a tubular heating furnace.

4. A reconfigurable photoelectric logic gate based on a non monotonic variation of a bismuth oxide open circuit photovoltage with a light intensity, comprising a working electrode, wherein the working electrode is a bismuth oxide film deposited on a conductive substrate, and the bismuth oxide film is prepared according to the preparation method according to claim 1.

5. The reconfigurable photoelectric logic gate based on the non monotonic variation of the bismuth oxide open circuit photovoltage with the light intensity according to claim 4, further comprising an input light source, a modulator, a counter electrode, an electrolyte and an electrolytic cell, wherein the input light source comprises a first input light source and a second input light source;
the input light source and the modulator are used to emit a light, wherein the light is used as an input light to illuminate a same position of the working electrode;
the working electrode is fixed inside the electrolytic cell, and the electrolytic cell serves as a container for the electrolyte; and
the counter electrode is fixed inside the electrolytic cell and does not block the light emitted by the input light source and the modulator.

6. The reconfigurable photoelectric logic gate based on the non monotonic variation of the bismuth oxide open circuit photovoltage with the light intensity according to claim 5, wherein the conductive substrate is one of stainless steel, a copper sheet, an aluminum sheet, indium tin oxide glass, a conductive silicon wafer, and fluorine-doped tin oxide glass.

7. The reconfigurable photoelectric logic gate based on the non monotonic variation of the bismuth oxide open circuit photovoltage with the light intensity according to claim 5, wherein the counter electrode is one of a platinum sheet, a copper sheet, a silver/silver chloride electrode, and a calomel electrode.

8. The reconfigurable photoelectric logic gate based on the non monotonic variation of the bismuth oxide open circuit photovoltage with the light intensity according to claim 5, wherein the input light source has a wavelength of 365 nm to 450 nm and a light intensity of 0.01 mW/cm² to 25 mW/cm².

9. An assembly method of a reconfigurable photoelectric logic gate, wherein the assembly method is based on the reconfigurable photoelectric logic gate according to claim 5, and comprises the following steps:
using quartz glass as a light input window;
fixing the working electrode inside the electrolytic cell and opposite to the quartz glass window, to ensure that the input light is allowed to illuminate the working electrode;
fixing the counter electrode inside the electrolytic cell, without blocking a light path of the input light; and
fixing three light sources as the first input light source, the second input light source and the modulator respectively, and adjusting the light path to allow the first input light source, the second input light source and the modulator to illuminate the same position of the working electrode.

10. A method for implementing logical calculation of a reconfigurable photoelectric logic gate, wherein the reconfigurable photoelectric logic gate is assembled according to the assembly method according to claim 9, and the method comprises the following steps:
injecting the electrolyte into the electrolytic cell, controlling switches and light intensities of the first input light source, the second input light source and the modulator, marking on states of the first input light source and the second input light source as 1, and marking off states of the first input light source and the second input light source as 0;
using a voltmeter to detect a variation of an open-circuit voltage at both ends of each of the working electrode and the counter electrode, and determining the open-circuit voltage as 1 when the open-circuit voltage is greater than a threshold, or determining the open-circuit voltage as 0 when the open-circuit voltage is less than the threshold; and
adjusting the light intensities of the first input light source, the second input light source and the modulator, to freely reconfigure an XOR gate, a multi-input XOR gate, an AND gate, a NAND gate, an OR gate, a NOR gate, a NOT gate and an AND-NOT gate on a single device, without changing the threshold.

11. The reconfigurable photoelectric logic gate based on the non monotonic variation of the bismuth oxide open circuit photovoltage with the light intensity according to claim 4, wherein in step (1) of the preparation method, a magnetron sputtering method is used to deposit the bismuth on the conductive substrate to obtain the bismuth film.

12. The reconfigurable photoelectric logic gate based on the non monotonic variation of the bismuth oxide open circuit photovoltage with the light intensity according to claim 4, wherein in step (2) of the preparation method, a temperature of the calcining is controlled to be 450 K to 720 K; and the calcining is carried out in any one of a heating table, a high-temperature oven, and a tubular heating furnace.

13. The reconfigurable photoelectric logic gate based on the non monotonic variation of the bismuth oxide open circuit photovoltage with the light intensity according to claim 11, further comprising an input light source, a modulator, a counter electrode, an electrolyte and an electrolytic cell, wherein the input light source comprises a first input light source and a second input light source;
the input light source and the modulator are used to emit a light, wherein the light is used as an input light to illuminate a same position of the working electrode;
the working electrode is fixed inside the electrolytic cell, and the electrolytic cell serves as a container for the electrolyte; and
the counter electrode is fixed inside the electrolytic cell and does not block the light emitted by the input light source and the modulator.

14. The reconfigurable photoelectric logic gate based on the non monotonic variation of the bismuth oxide open circuit photovoltage with the light intensity according to claim 13, wherein the conductive substrate is one of stainless steel, a copper sheet, an aluminum sheet, indium tin oxide glass, a conductive silicon wafer, and fluorine-doped tin oxide glass.

15. The reconfigurable photoelectric logic gate based on the non monotonic variation of the bismuth oxide open circuit photovoltage with the light intensity according to claim 13, wherein the counter electrode is one of a platinum sheet, a copper sheet, a silver/silver chloride electrode, and a calomel electrode.

16. The reconfigurable photoelectric logic gate based on the non monotonic variation of the bismuth oxide open circuit photovoltage with the light intensity according to claim 13, wherein the input light source has a wavelength of 365 nm to 450 nm and a light intensity of 0.01 mW/cm² to 25 mW/cm².

17. The reconfigurable photoelectric logic gate based on the non monotonic variation of the bismuth oxide open circuit photovoltage with the light intensity according to claim 12, further comprising an input light source, a modulator, a counter electrode, an electrolyte and an electrolytic cell, wherein the input light source comprises a first input light source and a second input light source;
the input light source and the modulator are used to emit a light, wherein the light is used as an input light to illuminate a same position of the working electrode;
the working electrode is fixed inside the electrolytic cell, and the electrolytic cell serves as a container for the electrolyte; and
the counter electrode is fixed inside the electrolytic cell and does not block the light emitted by the input light source and the modulator.

18. The reconfigurable photoelectric logic gate based on the non monotonic variation of the bismuth oxide open circuit photovoltage with the light intensity according to claim 17, wherein the conductive substrate is one of stainless steel, a copper sheet, an aluminum sheet, indium tin oxide glass, a conductive silicon wafer, and fluorine-doped tin oxide glass.

19. The reconfigurable photoelectric logic gate based on the non monotonic variation of the bismuth oxide open circuit photovoltage with the light intensity according to claim 17, wherein the counter electrode is one of a platinum sheet, a copper sheet, a silver/silver chloride electrode, and a calomel electrode.

20. The reconfigurable photoelectric logic gate based on the non monotonic variation of the bismuth oxide open circuit photovoltage with the light intensity according to claim 17, wherein the input light source has a wavelength of 365 nm to 450 nm and a light intensity of 0.01 mW/cm² to 25 mW/cm².
